(19) United States
(12) Patent Application Publication
(10) Pub. No.: US 2016/0365540 A1
(43) Pub. Date: Dec. 15, 2016

(54) THIN FILM PACKAGE STRUCTURE, MANUFACTURING METHOD AND ORGANIC LIGHT EMITTING APPARATUS HAVING THE STRUCTURE

(71) Applicant: EVERDISPLAY OPTRONICS (SHANGHAI) LIMITED, Shanghai (CN)

(72) Inventor: Ling XIAO, SHANGHAI (CN)

(73) Assignee: EVERDISPLAY OPTRONICS (SHANGHAI) LIMITED, SHANGHAI (CN)

(21) Appl. No.: 15/165,697

(22) Filed: May 26, 2016

(30) Foreign Application Priority Data
Jun. 12, 2015 (CN) 201510320653.2

(51) Int. Cl. H01L 51/52; H01L 51/56

(52) U.S. Cl. CPC H01L 51/5256; H01L 51/56; H01L 2251/303; H01L 2251/558

(57) ABSTRACT

The present disclosure relates to a thin film package structure, a method for manufacturing the structure and an organic light emitting apparatus including the structure. The thin film package structure is formed by inorganic thin film layers and organic thin film layers which are laminated alternately, the uppermost layer and the lowermost layer are inorganic thin film layers, the total number of the inorganic thin film layers and the organic thin film layers is not smaller than three, and at least one of the inorganic thin film layers is formed by at least two inorganic materials.

### CROSS-REFERENCE TO RELATED APPLICATIONS

This application is based upon and claims priority to Chinese Patent Application 201510320653.2, filed Jun. 12, 2015, the entire contents of which are incorporated herein by reference.

### TECHNICAL FIELD

The present disclosure generally relates to package structures of electronic elements, and more particularly, to a thin film package structure, a method for manufacturing the thin film package structure and an organic light emitting apparatus having the structure.

### BACKGROUND

Organic Light Emitting Devices (OLEDs) have low power consumption, small size, high brightness, wide field of view and fast response, and can provide a flexible display, and thereby are widely applied in smart terminals such as smart phones, and tablet computers.

At present, there are some problems in OLEDs which restrict the industrialization process of OLEDs. Among these problems, device lifetime is of central importance. On the one hand, lifetime of OLEDs relates to properties and lifetime of organic materials, and on the other hand relates to package method of OLEDs. This is because the organics and cathodes in the OLEDs are inclined to react with the moisture and oxygen. Especially, the devices employ active metal having a thickness of tens of nanometers as the cathodes, and the metal can fully react even with a small number of moisture or oxygen. Thus, the properties or characteristics of these materials are degraded or the materials may become ineffective, and consequently the devices may become ineffective. Thus, how to improve the package effect of the devices to make respective functional layers of the devices separated from the moisture or oxygen, and the like in the ambient environment is vital for lengthening device lifetime.

In conventional OLED packages, electrodes and respective functional layers are prepared on a substrate, and then the substrate having good chemical stability, compactness, and electrical insulating property is used as a protection cover to protect the devices. However, glass substrates have bad mechanical property and cracks and glue interruption are inclined to appear, and thus cannot meet the requirements of flexible display. Further, the glass substrates occupy relatively large space and do not fit the trend of small-sized OLEDs.

Some new package processes employ a Thin Film Package (TFE) technology which forms a physical protection on devices in a package region by forming a thin film of compact structure and is a gap-free package method. The existing inorganic thin film package structure has a good moisture/oxygen-resistance property, but its flexibility is not satisfactory. And, thin films having good flexibility are of bad moisture/oxygen-resistance property, for example, a polymer film.

### SUMMARY

In order to overcome the deficiencies in conventional technologies, the present disclosure provides a thin film package structure for packaging functional devices on a substrate. The thin film package structure is formed by inorganic thin film layers and organic thin film layers which are laminated alternately, the uppermost layer and the lowermost layer are inorganic thin film layers, the total number of the inorganic thin film layers and the organic thin film layers is not smaller than three, and at least one of the inorganic thin film layers is formed by at least two inorganic materials.

In an embodiment, the inorganic materials are oxides, nitrides, nitrogen oxides, or fluorides.

In an embodiment, the inorganic materials are metal oxides.

In an embodiment, at least one of the inorganic thin film layers is formed by two inorganic materials, and a weight ratio of the two inorganic materials in the at least one of inorganic thin film layers is 1:99˜99:1.

In an embodiment, the weight ratio of the two inorganic materials in at least one of the inorganic thin film layers is 1:2˜2:1.

In an embodiment, the two inorganic materials are aluminum oxide and zirconia, or aluminum oxide and zinc oxide.

In an embodiment, the organic thin film layers are formed by at least one organic material organic material selected from a group consisting of acryl-based polymer, silicon-based polymer, and epoxy-based polymer.

In an embodiment, the organic thin film layers are formed by at least one t organic material selected from a group consisting of polyamide, polyimide, polycarbonate, polypropylene, polyacrylic acid, polyacrylate, urethane acrylate, polyester, polyethylene, polystyrene, polysiloxane, polysilazane, and epoxylite.

In an embodiment, thicknesses of the inorganic thin film layers are 5˜2000 nm.

In an embodiment, the thicknesses of the inorganic thin film layers are 200˜1000 nm.

In an embodiment, thicknesses of the organic thin film layers are 50 nm˜15 μm.

In an embodiment, the thicknesses of the organic thin film layers are 2˜10 μm.

In an embodiment, a thickness of the thin film package structure is 100 nm˜50 μm.

In an embodiment, the thickness of the thin film package structure is 1˜20 μm.

The present disclosure further provides a method for manufacturing the above thin film package structure. In the method, the inorganic thin film layers are prepared using facing target sputtering.

In an embodiment, the organic thin film layers are prepared by selectively using spin coating, spraying, screen printing, ink jet printing, and chemical vapor deposition.

The present disclosure further provides an organic light emitting apparatus, including:

a substrate; and

an OLED and the above thin film package structure on the substrate, wherein the thin film package structure is used for packaging the OLED.

As compared with conventional technologies, the thin film package structure provided by the present disclosure at least has the following advantageous effects:

(1) The alternately laminated inorganic thin film layers and organic thin film layers have a good moisture/oxygen-resistance property, and thus can effectively lengthen device lifetime.

(2) The thin film package structure can make the devices realize a flexible function, and can meet miniaturization requirements of the devices.

(3) The package process is easy to operate and applicable for mass production. Further, there is no release of pollution gases during the package process.

### BRIEF DESCRIPTION OF THE DRAWINGS

FIGS. 1-3 are schematic diagrams showing thin film package structures according to different embodiments of the present disclosure; and

FIG. 4 is a schematic diagram showing Facing Target Sputtering (FTS) according to an embodiment of the present disclosure.

Reference number as listed as follows:
10 substrate
20 functional device
30 inorganic thin film layers
40 organic thin film layers
50 mask
60 first target
70 second target

### DETAILED DESCRIPTION

Now exemplary embodiments will be described more fully with reference to the accompanying drawings. However, the exemplary embodiments may be embodied in various forms, and should not be construed as limited to the embodiments set forth herein. Rather, these embodiments are provided so that this disclosure will be thorough and complete, and fully convey the concept of the exemplary embodiments to those skilled in the art. In the drawings, the same reference numerals denote the same or similar structure, and therefore a repetitive description thereof will be omitted.

The terminologies “first”, and “second” are only intended for description purposes but cannot be interpreted as an indication or a hint of relative importance or an implied indication of the number of the identified technical features.

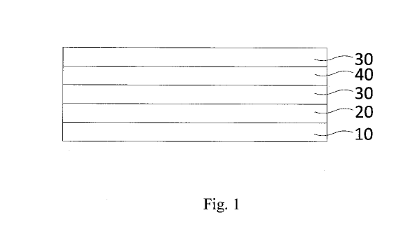

As shown in FIG. 1, the thin film package structure of the present disclosure is used for packaging a functional device 20 on one side of a substrate 10. The substrate 10 may be formed by glass, metal or plastic. The functional device 20 in the present disclosure includes but not limited to OLEDs and solar cells. When the functional device 20 is an OLED, a TFT (Thin Film Transistor) array, an anode, a hole transport layer, a light emitting layer, an electron transport layer and a cathode are arranged in sequence from top to bottom in the functional device 20. And, the functional device 20 may further include a hole injection layer and an electron injection layer, and the like.

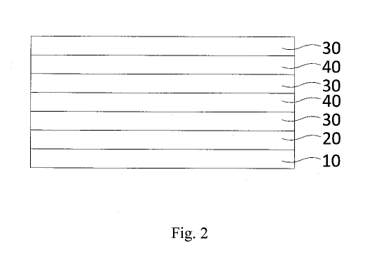

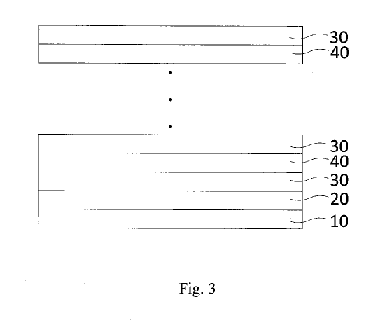

The thin film package structure of the present disclosure is formed by inorganic thin film layers 30 and organic thin film layers 40 which are laminated alternately. The uppermost layer and the lowermost layer are inorganic thin film layers 30, and the total number of the inorganic thin film layers 30 and the organic thin film layers 40 is not smaller than three. At least one of the inorganic thin film layers 30 is formed by at least two inorganic materials. In an embodiment, as shown in FIG. 1, the thin film package structure is formed by three laminated layers including an inorganic thin film layer 30, an organic thin film layer 40 and another inorganic thin film layer 30. In other embodiment, as shown in FIGS. 2 and 3, the thin film package structure is formed by more inorganic thin film layers 30 and organic thin film layers 40 which are laminated alternately. In the thin film package structure, the inorganic thin film layers 30 have good moisture/oxygen-resistance property, and the organic thin film layer(s) 40 can effectively reduce the stress caused by the inorganic thin film layers 30. Further, minor cracks and pinholes may appear in the inorganic thin film layers 30 because of process factors, while the organic thin film layers 40 can block the moisture and oxygen from permeating inwards through the cracks and pinholes, and thereby can repair the above defects caused by the cracks and pinholes. Consequently, by blocking the moisture and oxygen, the package effect is further improved and the thin film package can realize a flexible function.

The thin film package structure can cover the surface and/or sides of the device 20 according to actual requirements. In the package structure, thicknesses of the inorganic thin film layers 30 may be within a range of 5˜2000 nm, preferably 200˜1000 nm, for example, 500 nm. The thicknesses of respective inorganic thin film layers 30 can be the same or different. The thicknesses of the inorganic thin film layers 40 may be within a range of 50 nm˜15 μm, preferably 2˜10 μm, for example, 3 μm. The thicknesses of respective organic thin film layers 40 can be the same or different. The thin film package structure may have a thickness within a range of 100 nm˜50 μm, preferably, 1˜20 μm, for example, 5 μm.

At least one of the inorganic thin film layers 30 may be formed by at least two inorganic materials, preferably two inorganic materials, and a weight ratio of the two inorganic materials in the at least one of the inorganic thin film layers is within a range of 1:99˜99:1, preferably 1:2˜2:1, more preferably 1:1. The inorganic materials include but not limited to oxides, nitrides, nitrogen oxides, or fluorides, preferably metal oxides. The oxides include but not limited to aluminum oxide, zirconia, zinc oxide, titanium oxide, magnesium oxide, or silicon oxide, preferably, aluminum oxide, zirconia, or zinc oxide. The nitrides include but not limited to silicon nitride, aluminum nitride, or titanium nitride. The nitrogen oxides include but not limited to silicon oxynitride, aluminum oxynitride or titanium oxynitride. The fluorides include but not limited to magnesium fluoride, or sodium fluoride.

More preferably, the two inorganic materials in one of the inorganic thin film layers 30 are preferably aluminum oxide and zirconia, or aluminum oxide and zinc oxide. The hybrid inorganic thin film layers have a more compact film structure and better moisture/oxygen-resistance effect as compared with a single inorganic thin film layer structure.

Aluminum oxide has an amorphous structure, and zirconia is monoclinic crystal system under a low temperature. If the inorganic thin film layers 30 employ a hybrid thin film layer of aluminum oxide and zirconia, the amorphous aluminum oxide can effectively restrict growth of zirconia in a certain direction and thus reduce defects, so that the aluminum oxide-zirconia thin film layer presents an amorphous state as a whole, and the surface toughness is greatly improved, which is helpful for forming even and compact organic thin film layers 40 on a surface of the hybrid inorganic thin film layer 30 of aluminum oxide-zirconia. Consequently, a protection layer of a high compactness is formed, thereby effectively preventing the moisture and oxygen in ambient environment from permeation.

Zinc oxide may preferably be zinc oxide crystal having a crystal structure. The zinc oxide crystal usually has a hexagonal wurtzite structure or a cubic zinc blende structure. During the formation of the inorganic thin film layers 30, the amorphous aluminum oxide can effectively restrict the growth of zinc oxide crystal in a certain direction and thereby reduce defects. Further, the formed hybrid inorganic thin film layer 30 of aluminum oxide and zirconia has a high transmittance in visible light range, up to 90% at the most, and thus may be applied in a top emission OLED.

The inorganic thin film layers 30 may be prepared by various existing physical deposition methods, including but not limited to evaporation, sputtering and ion plating, preferably, sputtering.

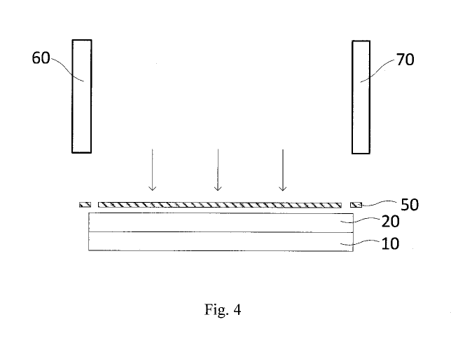

Further, the inorganic thin film layers 30 may be prepared using Facing Target Sputtering. For example, when the aluminum oxide/zirconia hybrid inorganic thin film layer 30 is formed, as shown in FIG. 4, an aluminum target and a zirconium target are prepared as a first target 60 and a second target 70. The two targets are arranged as a facing target state where the two targets face each other. Further, a mask 50 is provided. During sputtering, reaction gas such as oxygen gas is introduced to perform sputtering on the two targets. After reaction, a hybrid inorganic thin film layer 30 of aluminum oxide and zirconia is formed. The aluminum target and the zirconium target involved in the thin film deposition procedure are targets of high purity, preferably of a purity of 99.99%. The weight ratio of the aluminum oxide and zirconia in the hybrid inorganic thin film layer 30 is about 1:99˜99:1, and the weight ratio may be controlled by adjusting the sputtering power and flow rate of oxygen gas. When the inorganic thin film layer 30 is a nitride, a nitrogen oxide, or a fluoride, corresponding nitride, nitrogen oxide, or fluoride may be used as the first target 60 and the second target 70.

The sizes of the first target 60 and the second target 70 may be 50×200 mm², 100×300 mm² or 200×300 mm², and the like. The inorganic thin film layer 30 formed using the above method has a relatively high compactness, and may effectively block the permeation of moisture and oxygen in ambient environment. Further, during the deposition of the inorganic thin film layer 30, the facing target sputtering method imposes smaller forces on the device as compared with the magnetron sputtering method, thereby greatly reducing the damage on the electrodes and function layers of the device. During the sputtering, the film forming rate is relatively high, and no chemical gas is introduced or released, and thus the sputtering method has no environment threats. Consequently, an environment-friendly package is arrived at.

The organic thin film layer 40 is formed by at least one organic material capable of effectively blocking moisture and oxygen. In an embodiment, the materials of the organic thin film layer 40 may be organic polymer materials, which may include but not limited to acryl-based polymer, silicon-based polymer and epoxy-based polymer, preferably, polyamide, polyimide, polycarbonate (PC), polypropylene (PP), polyacrylic acid (PAA), polyacrylate, urethane acrylate, polyester, polyethylene (PE), polystyrene (PS), polysiloxane, polysilazane, or epoxylite.

In an embodiment, among the materials of the organic thin film layer 40, the polyamide includes but not limited to polyamide 6 (PA6), polyamide 66 (PA66), polyamide 7 (PA7), polyamide 9 (PA9), polyamide 10 (PA10), polyamide 11 (PA11), polyamide 12 (PA12), polyamide 69 (PA69), polyamide 610 (PA610), polyamide 612 (PA612), or polyphthalamide (PPA). The polyimide includes polyimide generated by dehydration reaction of dianhydride compound and diamine compound. The dianhydride compound includes dianhydride compound of aromatic carboxylic acid dianhydride compound and aliphatic dianhydride compound. The diamine compound includes aromatic diamine compound and aliphatic diamine compound. Polycarbonate, depending on ester group structures, includes aliphatic polycarbonate, aromatic polycarbonate, aliphatic-aromatic polycarbonate, preferably, aromatic polycarbonate. Polyacrylate includes but not limited to polymethyl methacrylate (PMMA) and polyethyl methacrylate (PEMA). Polyester includes but not limited to polyethylene naphthalate (PEN), or polyethylene terephthalate (PET). Polysiloxane includes but not limited to methyl vinyl polysiloxane, dimethyl polysiloxane, methyl phenyl vinyl polysiloxane, or methyl phenyl polysiloxane. Polysilazane includes but not limited to perhydropolysilazane. Epoxylite may include bisphenol A type epoxy resin, bisphenol F type epoxy resin, bisphenol AD type epoxy resin, naphthalene type epoxy resin, biphenyl type epoxy resin, epoxy resin of glycidylamine, alicyclic epoxy resin, dicyclopentadiene type epoxy resin, polyether type epoxy resin, or silicone modified epoxy resin.

The organic thin film layer 40 may be prepared using physical or chemical methods, including but not limited to spin coating, spraying, screen printing, ink jet printing, or Chemical Vapor Deposition (CVD). The CVD may include atmospheric pressure CVD or PECVD (Plasma Enhanced Chemical Vapor Deposition). Ink jet printing is a preferred method. Further, after spin coating, spraying, screen printing, or ink jet printing, heat curing is also needed.

Taking the packaging of an OLED as an example, an exemplary method for preparing the thin film package structure may include the following steps:

(1) putting the OLED arranged on one side of the substrate 10 in a sputtering chamber, and preparing an inorganic thin film layer 30 with a thickness of 5˜2000 nm using facing target sputtering;

(2) preparing an organic thin film layer 40 with a thickness of 50 nm˜15 μm on the inorganic thin film 30 of the OLED;

(3) repeating steps (1) and (2) to form inorganic thin film layers 30 and organic thin film layers 40 which are alternately laminated, wherein the topmost and lowermost layers are inorganic thin film layers 30, and the thickness of the formed thin film package structure is 100 nm˜50 μm.

In the thin film package structure formed by alternately laminated inorganic thin film layers 30 and organic thin film layers 40, the formed thin film is solid, compact and uniform, and may realize good package effect. Further, the thin film package structure can greatly reduce device weight. Meanwhile, the above process is easy to operate, and no special equipment is needed, and thus is helpful for mass production and costs reduction.

In a first example, an aluminum oxide-zirconia/PMMA thin film package structure is formed using the following steps:

(1) putting the OLED arranged on one side of the substrate 10 in a sputtering chamber in which there are a first target 60 and a second target 70 which are an aluminum target and a zirconium target of high purity, respectively, and introducing reaction gas such as oxygen gas and preparing an inorganic thin film layer 30 with a thickness of about 500 nm using facing target sputtering;

(2) preparing an organic thin film layer 40 of polyimide with a thickness of about 3 μm on the inorganic thin film layer 30 of the OLED using spin coating;

(3) repeating steps (1) and (2) to form inorganic thin film layers 30 and organic thin film layers 40 which are alternately laminated, wherein the topmost and lowermost layers are inorganic thin film layers 30, the number of the thin film layers is three, and the thickness of the resulted thin film package structure is 4 μm.

In a second example, an aluminum oxide-zirconia/PMMA thin film package structure is formed using the following steps:

(1) putting the OLED arranged on one side of the substrate 10 in a sputtering chamber in which there are a first target 60 and a second target 70 which are an aluminum target and a zirconium target of high purity, respectively, and introducing reaction gas such as oxygen gas and preparing an inorganic thin film layer 30 with a thickness of about 100 nm using facing target sputtering;

(2) preparing an organic thin film layer 40 of polysiloxane-polysilazane with a thickness of about 300 nm on the inorganic thin film layer 30 of the OLED by coating;

(3) repeating steps (1) and (2) to form inorganic thin film layers 30 and organic thin film layers 40 which are alternately laminated, wherein the topmost and lowermost layers are inorganic thin film layers 30, the number of the thin film layers is 21, and the thickness of the resulted thin film package structure is 4.1 μm.

Even though the thin film package structure in the present disclosure is described with an example of OLED package, it shall be understood that the thin film package in the present disclosure may be applied in other same or similar packages or package technologies to realize package/encapsulation of elements or devices. It shall be noted that the present disclosure is not limited to the disclosed embodiments but is intended to encompass various modifications and equivalent replacements within the protection scope as defined in appended claims.

What is claimed is:

1. A thin film package structure, applied in functional devices on a package substrate, wherein the thin film package structure is formed by inorganic thin film layers and organic thin film layers which are laminated alternately, the uppermost layer and the lowermost layer are inorganic thin film layers, the total number of the inorganic thin film layers and the organic thin film layers is not smaller than three, and at least one of the inorganic thin film layers is formed by at least two inorganic materials.

2. The thin film package structure according to claim 1, wherein the inorganic materials are oxides, nitrides, nitrogen oxides, or fluorides.

3. The thin film package structure according to claim 2, wherein the inorganic materials are metal oxides.

4. The thin film package structure according to claim 3, wherein at least one of the inorganic thin film layers is formed by two inorganic materials, and a weight ratio of the two inorganic materials in the at least one of inorganic thin film layers is 1:99˜99:1.

5. The thin film package structure according to claim 4, wherein the weight ratio of the two inorganic materials in at least one of the inorganic thin film layers is 1:2˜2:1.

6. The thin film package structure according to claim 4, wherein the two inorganic materials are aluminum oxide and zirconia, or aluminum oxide and zinc oxide.

7. The thin film package structure according to claim 1, wherein the organic thin film layers are formed by at least one organic material selected from a group consisting of acryl-based polymer, silicon-based polymer, and epoxy-based polymer.

8. The thin film package structure according to claim 1, wherein the organic thin film layers are formed by at least one organic material selected from a group consisting of polyamide, polyimide, polycarbonate, polypropylene, polyacrylic acid, polyacrylate, urethane acrylate, polyester, polyethylene, polystyrene, polysiloxane, polysilazane, and epoxylite.

9. The thin film package structure according to claim 1, wherein thicknesses of the inorganic thin film layers are 5˜2000 nm.

10. The thin film package structure according to claim 9, wherein the thicknesses of the inorganic thin film layers are 200˜1000 nm.

11. The thin film package structure according to claim 1, wherein thicknesses of the organic thin film layers are 50 nm˜15 μm.

12. The thin film package structure according to claim 11, wherein the thicknesses of the organic thin film layers are 2˜10 μm.

13. The thin film package structure according to claim 1, wherein a thickness of the thin film package structure is 100 nm˜50 μm.

14. The thin film package structure according to claim 13, wherein the thickness of the thin film package structure is 1˜20 μm.

15. A method for manufacturing a thin film package structure, the thin film package structure is applied in functional devices on a package substrate, the thin film package structure is formed by inorganic thin film layers and organic thin film layers which are laminated alternately, the uppermost layer and the lowermost layer are inorganic thin film layers, the total number of the inorganic thin film layers and the organic thin film layers is not smaller than three, and at least one of the inorganic thin film layers is formed by at least two inorganic materials;
wherein the method comprises:
preparing the inorganic thin film layers using facing target sputtering.

16. The method for manufacturing a thin film package structure according to claim 15, further comprising:
preparing the organic thin film layers by selectively using spin coating, spraying, screen printing, ink jet printing, and chemical vapor deposition.

17. An organic light emitting apparatus, comprising:
a substrate; and
an Organic Light Emitting Device (OLED) and a thin film package structure on the substrate;
wherein the thin film package structure is used for packaging the OLED, the thin film package structure is formed by inorganic thin film layers and organic thin film layers which are laminated alternately, the uppermost layer and the lowermost layer are inorganic thin film layers, the total number of the inorganic thin film layers and the organic thin film layers is not smaller than three, and at least one of the inorganic thin film layers is formed by at least two inorganic materials.

18. The organic light emitting apparatus according to claim 17, wherein the inorganic materials are selected from a group consisting of oxides, nitrides, nitrogen oxides, and fluorides.

19. The organic light emitting apparatus according to claim 18, wherein the inorganic materials are metal oxides.

20. The organic light emitting apparatus according to claim 18, wherein at least one of the inorganic thin film layers is formed by two inorganic materials, and a weight ratio of the two inorganic materials in the at least one of inorganic thin film layers is 1:99˜99:1.
